(19) United States
(12) Patent Application Publication
(10) Pub. No.: US 2011/0103598 A1
(43) Pub. Date: May 5, 2011

(54) RADIO COMMUNICATION APPARATUS, METHOD, AND COMPUTER PROGRAM FOR NOTIFICATION OF EVENT OCCURRENCE

(75) Inventors: Kenji Fukui, Kawasaki (JP); Akinobu Ueda, Kawasaki (JP)

(73) Assignee: FUJITSU LIMITED, Kawasaki-shi (JP)

(21) Appl. No.: 12/916,056

(22) Filed: Oct. 29, 2010

(30) Foreign Application Priority Data
Nov. 4, 2009 (JP) 2009-252919

(51) Int. Cl. H03G 3/20; G08B 21/00

(52) U.S. Cl. 381/57; 340/540

(57) ABSTRACT

A radio communication apparatus including: a sound notification unit that to provide sound-based notification of an occurrence of an event related to the at least one application; a non-sound notification unit to provide non-sound-based notification of an occurrence of an event related to the at least one application; a memory to store a notification sound volume associated with an application, the notification sound volume being a volume of a notification sound produced by the sound notification unit to provide notification of an occurrence of an event related to the application; a sound collecting unit to collect ambient sound; and a processor to select a notification method on the basis of whether an ambient sound volume is greater than the notification sound volume stored in the memory, the ambient sound volume being a volume of the ambient sound collected by the sound collecting unit.

### CROSS-REFERENCE TO RELATED APPLICATIONS

This application is related to and claims priority to Japanese Patent Application No. 2009-252919 filed on Nov. 4, 2009 and herein incorporated by reference.

### FIELD

The present invention relates to a radio communication apparatus and methods for notifying a user of an occurrence of an event.

### BACKGROUND

When an event (e.g., reception of an incoming call or a mail message) that involves notification to a user occurs, a portable radio communication apparatus, such as a mobile phone that can be carried by the user, can notify the user of the occurrence of the event by emitting a sound signal at a given volume.

However, if the level of noise around the user is high, it may be difficult for the user to realize the sound signal that indicates the occurrence of the event.

For mobile phones, there has been developed a technique that automatically controls a state of notification of an incoming call in accordance with the surrounding environment at the time of reception of an incoming call (see, e.g., Japanese Unexamined Patent Application Publication No. 10-341464).

In this technique, a sample of given sound pressure data is compared with sound pressure data that represents sound pressure measured around the mobile phone at the time of reception of an incoming call. On the basis of this comparison, a determination is made as to which of a speaker and a vibrator is to be used. At the same time, a ring tone volume is automatically adjusted in accordance with environmental conditions around the mobile phone.

### SUMMARY

According to an embodiment, a radio communication apparatus includes: a sound notification unit to provide sound-based notification of an occurrence of an event related to the at least one application; a non-sound notification unit to provide non-sound-based notification of an occurrence of an event related to the at least one application; a memory to store a notification sound volume associated with an application, the notification sound volume being a volume of a notification sound produced by the sound notification unit to provide notification of an occurrence of an event related to the application; a sound collecting unit to collect ambient sound; and a processor to select a notification method on the basis of whether an ambient sound volume is greater than the notification sound volume stored in the memory, the ambient sound volume being a volume of the ambient sound collected by the sound collecting unit.

An object and advantages of the present invention are implemented and achieved by elements specified in claims and combinations of the elements.

It is to be understood that both the general description above and the detailed description below are provided for exemplary and explanatory purposes and are, unlike the claims, not intended to limit the scope of the present invention.

### BRIEF DESCRIPTION OF THE DRAWINGS

FIG. 1 illustrates a configuration of a mobile phone according to an embodiment.

FIG. 2 is a functional block diagram illustrating functions for selecting an event-occurrence notification method for each application, the functions being realized by a controller included in the mobile phone illustrated in FIG. 1.

FIG. 3 illustrates an example of an ambient sound level table.

FIG. 4 illustrates an example of a notification method table showing a notification method for each application.

FIG. 5 is an operation flowchart illustrating a process of periodically selecting an event-occurrence notification method for each application, the process being executed by the controller illustrated in FIG. 2.

FIG. 6 is an operation flowchart illustrating a process of selecting a notification method for a specific application when an event occurs and providing notification of the occurrence of the event using the selected notification method, the process being executed by the controller illustrated in FIG. 2.

FIG. 7 illustrates a configuration of a personal digital assistant according to another embodiment.

### DESCRIPTION OF THE EMBODIMENTS

Many portable radio communication apparatuses that have been widespread in recent years are capable of executing a plurality of different applications. Examples of such applications include telephony, electronic mail, short message service, alarm, and scheduler applications that notify the user of occurrences of given events. In such a portable radio communication apparatus, a volume of a notification sound for providing notification of an event occurrence can be set to a different value for each application. For example, when a set volume of a notification sound is large, the user can notice the notification even if the portable radio communication apparatus provides notification of an event occurrence by sound in noisy environment. However, if a set volume of a notification sound is small, noise may prevent the user from noticing the notification when the portable radio communication apparatus provides the notification of an event occurrence by sound.

The present specification provides a radio communication apparatus, a computer program for notification of an event occurrence, and a method for notification of an event occurrence that make it possible to select an event-occurrence notification method for each application in accordance with an ambient sound volume.

A mobile phone according to an embodiment will now be described with reference to the drawings. The mobile phone measures a volume of ambient sound around the mobile phone, and compares the ambient sound volume with a volume of a notification sound for providing notification of an occurrence of an event related to each application running on the mobile phone. For an application whose notification sound volume is lower than the ambient sound volume, the mobile phone provides notification of an event occurrence by vibration, instead of sound.

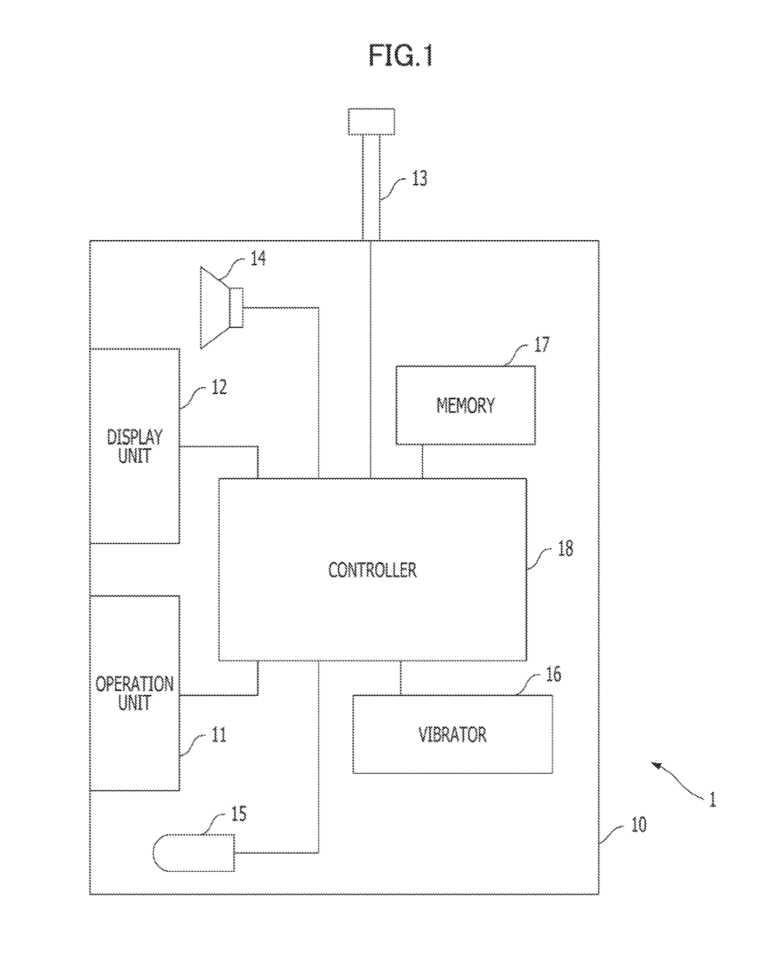

FIG. 1 illustrates a configuration of a mobile phone 1 according to an embodiment.

As illustrated in FIG. 1, the mobile phone 1 includes an operation unit 11, a display unit 12, an antenna 13, a speaker 14, a microphone 15, a vibrator 16, a memory 17, and a controller 18. The mobile phone 1 has a housing 10 for accommodating these components. The operation unit 11, the display unit 12, the antenna 13, the speaker 14, the microphone 15, the vibrator 16, and the memory 17 are, for example, individually connected to the controller 18. The mobile phone 1 has a power supply unit for supplying power, for example, to the controller 18 and the display unit 12. The mobile phone 1 may have a camera and a near field communication interface, such as an infrared port.

The operation unit 11 may be used by a user of the mobile phone 1 to operate the mobile phone 1. The operation unit 11 has, for example, a plurality of key button switches on the front side of the housing 10. When the user presses any of the key button switches, the operation unit 11 transmits an operation signal corresponding to the pressed key button switch to the controller 18. By operating the operation unit 11 in accordance with an instruction from an application running on the mobile phone 1, the user can make the mobile phone 1 perform a given operation. For example, by operating the operation unit 11, the user can set, for each application, a method for notification of an event occurrence to a sound-based (e.g., acoustic) notification method using a voice, a melody, a ring tone, or the like from the speaker 14, or to a vibration-based notification method using a vibration from the vibrator 16. Additionally, by operating the operation unit 11, the user can set, for each application, a volume of a notification sound to any of a plurality of notification sound volume levels, the notification sound being used when a sound-based notification method using a voice, a melody, a ring tone, or the like is used. In the following description, a volume of a notification sound is simply referred to as a notification sound volume.

The display unit 12 displays information provided to the user by an application running on the mobile phone 1, or displays information input by the user through the operation unit 11. The display unit 12 has, for example, at least one thin display device, such as a liquid crystal display or an organic electro-luminescence (EL) display. The display unit 12 may be attached to the front or back side of the housing 10 such that the screen of the display unit 12 is oriented toward the outside of the housing 10. Upon receipt of a signal containing information to be displayed from the controller 18, the display unit 12 displays the information contained in the signal. The operation unit 11 and the display unit 12 may be configured as an integral unit, such as a touch-panel display.

The antenna 13 is used by the mobile phone 1 to communicate with a base station. The antenna 13 may be used to receive information for positional measurement from a global positioning system (GPS) satellite. The antenna 13 may be retractably attached to an upper part of the housing 10. A signal received from a base station or a GPS satellite through the antenna 13 is passed to the controller 18. A signal received from the controller 18 is transmitted through the antenna 13 to a base station.

The speaker 14 functions as a sound notification unit. For example, the speaker 14 outputs a call voice or a notification sound that provides notification of an occurrence of an event related to any application running on the mobile phone 1. Examples of the notification sound include a voice, a melody, and a ring tone. The speaker 14 has, for example, an electrodynamic speaker, a piezoelectric speaker, or another type of small speaker. The speaker 14 converts a sound signal received from the controller 18 into an air vibration corresponding to the intensity of the sound signal. The speaker 14 and the display unit 12 may be configured as an integral unit, such as a display speaker.

The microphone 15 functions as a sound collecting unit. The microphone 15 collects user's voice, ambient sound around the mobile phone 1, or ambient sound including user's voice. The microphone 15 has, for example, an electric capacitor microphone, a piezoelectric microphone, or another type of small microphone. The microphone 15 converts collected ambient sound into a sound signal having an intensity corresponding to the volume of the ambient sound, and transmits the sound signal to the controller 18.

The vibrator 16 functions as a non-sound notification unit that generates a human perceivable phenomenon, other than sound. For example, the vibrator 16 may generate a given vibration to cause the housing 10 to vibrate. The vibrator 16 has, for example, a motor and an eccentric weight attached to a rotation axis of the motor. Upon receipt of a signal that represents an instruction from the controller 18 to generate a vibration, the vibrator 16 rotates the motor to generate a vibration.

The memory 17 has, for example, a nonvolatile semiconductor memory and a volatile semiconductor memory. The memory 17 stores at least one application program executed by the mobile phone 1. The memory 17 also stores setting information, user's personal setting information, and various kinds of data that are used by the application program. For each application, the memory 17 stores a flag that indicates a type of notification method for notifying the user of an occurrence of an event when the event occurs.

In the present embodiment, examples of a method for notifying the user of an event occurrence include a sound-based notification method using a sound emitted by the speaker 14, and a vibration-based notification method using a vibration generated by the vibrator 16. When the mobile phone 1 notifies the user of an occurrence of an event by sound, the memory 17 stores a volume level of a notification sound to be emitted by the speaker 14.

The controller 18 includes at least one processor and its peripheral circuit. The controller 18 executes processing related to various applications implemented in the mobile phone 1. For each application, the controller 18 periodically selects a method using a sound emitted by the speaker 14 or a method using a vibration generated by the vibrator 16 as an event-occurrence notification method, and stores the selected notification method in the memory 17. When an event occurs, the controller 18 notifies the user of the occurrence of the event in accordance with the notification method stored in the memory 17. Alternatively, when an event occurs, the controller 18 selects, for an application related to the event, a sound-based notification method or a vibration-based notification method, and notifies the user of the occurrence of the event using the selected notification method.

Examples of applications implemented in the mobile phone 1 include telephony, electronic mail, short message service, alarm, scheduler, and navigator applications. The event may be, for example, receipt of an incoming call, an electronic mail message, or a short message. The event may mean that the current time has reached an alarm time set in an alarm or a scheduler, or that the current location of the mobile phone 1 has reached a given location.

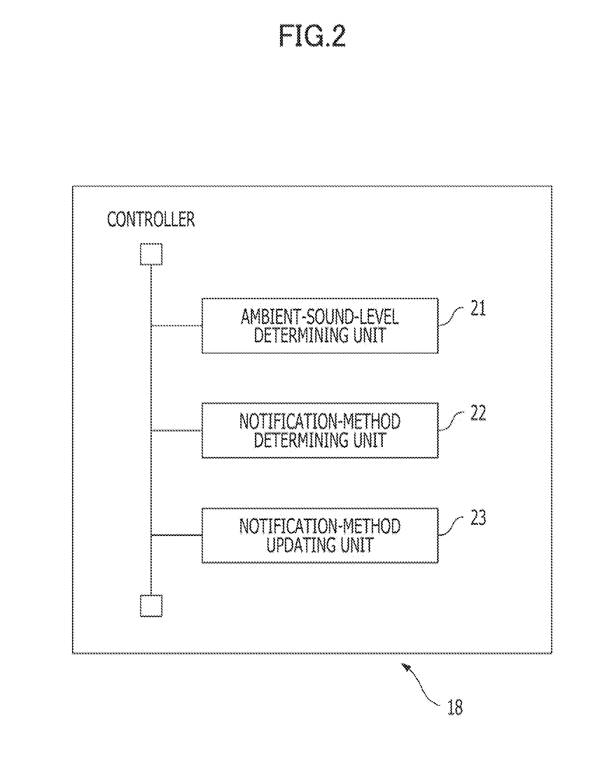

FIG. 2 is a functional block diagram illustrating the controller 18. Specifically, FIG. 2 illustrates functions realized for selecting an event-occurrence notification method for each application. As illustrated in FIG. 2, the controller 18 includes an ambient-sound-level determining unit 21, a notification-method determining unit 22, and a notification-method updating unit 23. These components of the controller 18 may be functional modules implemented by a computer program running on a processor included in the controller 18. Alternatively, these components of the controller 18 may be implemented as firmware in the mobile phone 1.

The controller 18 includes modules for executing processing for respective applications, and modules for controlling the mobile phone 1 such as a communication control module and a power management module. Since modules other than those illustrated in FIG. 2 (i.e., the modules for executing processing for respective applications) are not directly related to selection of a notification method, the following describes only the components illustrated in FIG. 2.

The ambient-sound-level determining unit 21 converts a volume of ambient sound collected by the microphone 15 into an ambient sound level corresponding to a level of a notification sound volume for each application. This is to compare the volume of ambient sound with the notification sound volume. For example, the ambient-sound-level determining unit 21 converts an intensity of a sound signal received from the microphone 15 by the controller 18 into a value in decibels using the following equation:

$$L = 10 \times {log}_{10} \frac{I}{{I}_{0}} \qquad ( 1 )$$

where “I” represents an intensity of a sound signal received from the microphone 15 by the controller 18; “I₀” represents an intensity of a reference sound and is a signal value equivalent to 10⁻¹² (W/m²); and “L” represents the intensity of the sound signal, the intensity being expressed in decibels. Hereinafter, an intensity of a sound signal, the intensity being expressed in decibels, is referred to as an ambient sound value.

The ambient-sound-level determining unit 21 refers to an ambient sound level table to determine an ambient sound level corresponding to an ambient sound value. The ambient sound level table shows a correspondence between an ambient sound value and an ambient sound level. An ambient sound level corresponds to a notification sound volume level in each application. That is, if a value of an ambient sound level at some point in time is substantially equal to a value of a notification sound volume level for a given application, the user will feel that the volume of ambient sound is substantially the same as the volume of the notification sound emitted by the mobile phone 1 in accordance with the given application.

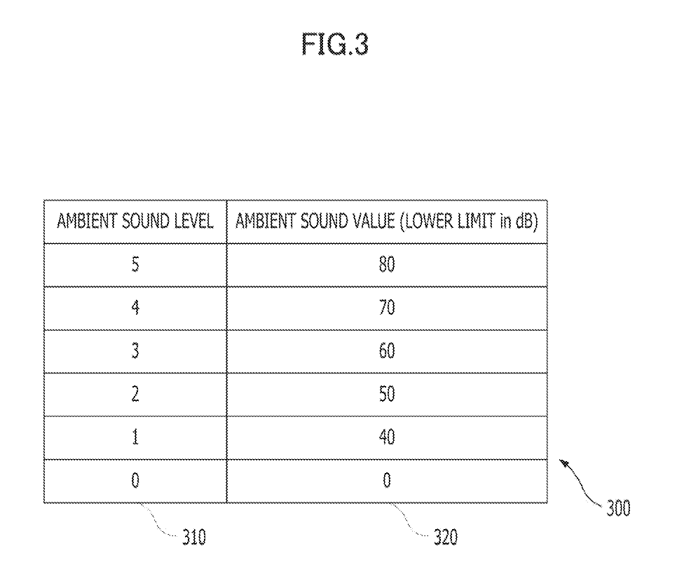

A correspondence between an ambient sound value and an ambient sound level may be determined in advance by experiment or simulation. An ambient sound level table showing this correspondence is stored in the memory 17. FIG. 3 illustrates an example of an ambient sound level table. In an ambient sound level table 300 of FIG. 3, a column 310 on the left shows ambient sound levels and a column 320 on the right shows lower limits of ambient sound values corresponding to the respective ambient sound levels. In the ambient sound level table 300, the ambient sound levels are represented by integers from “0” to “5”. The ambient sound level “0” corresponds to a minimum sound volume, and the ambient sound level “5” corresponds to a maximum sound volume.

For example, when an obtained ambient sound value is less than 40 dB, the ambient-sound-level determining unit 21 refers to the ambient sound level table 300 to find that this ambient sound value is less than a lower limit corresponding to the ambient sound level “1”. The ambient-sound-level determining unit 21 determines that the ambient sound level corresponding to this ambient sound value is “0”.

When an obtained ambient sound value is equal to 60 dB or more and less than 70 dB, the ambient-sound-level determining unit 21 refers to the ambient sound level table 300 to find that this ambient sound value is less than a lower limit corresponding to the ambient sound level “4” and greater than a lower limit corresponding to the ambient sound level “3”. The ambient-sound-level determining unit 21 determines that the ambient sound level corresponding to this ambient sound value is “3”.

The ambient-sound-level determining unit 21 notifies the notification-method determining unit 22 of the determined ambient sound level. Such an ambient sound level table may show a correspondence between intensities of sound signals generated by the microphone 15 and ambient sound levels. In this case, without converting a sound signal into an ambient sound value expressed in decibels, the ambient-sound-level determining unit 21 can identify and directly determine an ambient sound level corresponding to an intensity of the sound signal by referring to the ambient sound level table.

Even when a notification sound volume level for an application is set to a minimum, an ambient sound value may be low enough for the user to realize the notification sound. In such a case, when the controller 18 operates to periodically select a notification method, the ambient-sound-level determining unit 21 does not have to determine an ambient sound level and does not have to notify the notification-method determining unit 22 of an ambient sound level. For example, when an ambient sound value is less than 40 dB, which corresponds to the ambient sound level “0” in the ambient sound level table 300 of FIG. 3, the ambient-sound-level determining unit 21 does not determine the ambient sound level. Thus, when an ambient sound value is low, the controller 18 can reduce an operation load. In this case, the ambient-sound-level determining unit 21 sends, to the notification-method updating unit 23, a low-ambient-sound signal indicating that the ambient sound value is low.

Each time an ambient sound level is received from the ambient-sound-level determining unit 21, the notification-method determining unit 22 determines, for each application, an event-occurrence notification method in accordance with the ambient sound level. The notification-method determining unit 22 compares the ambient sound level determined by the ambient-sound-level determining unit 21 with a notification sound volume level for each application. If the ambient sound level is higher than the notification sound volume level for the application, the notification-method determining unit 22 sets a vibration-based notification method as an event-occurrence notification method for the application. If the ambient sound level is lower than or equal to the notification sound volume level for the application, the notification-method determining unit 22 sets a sound-based notification method as an event-occurrence notification method for the application. To compare an ambient sound level with a notification sound volume level for each application, the notification-method determining unit 22 reads, from the memory 17, a notification method table showing a notification method and a notification sound volume for each application.

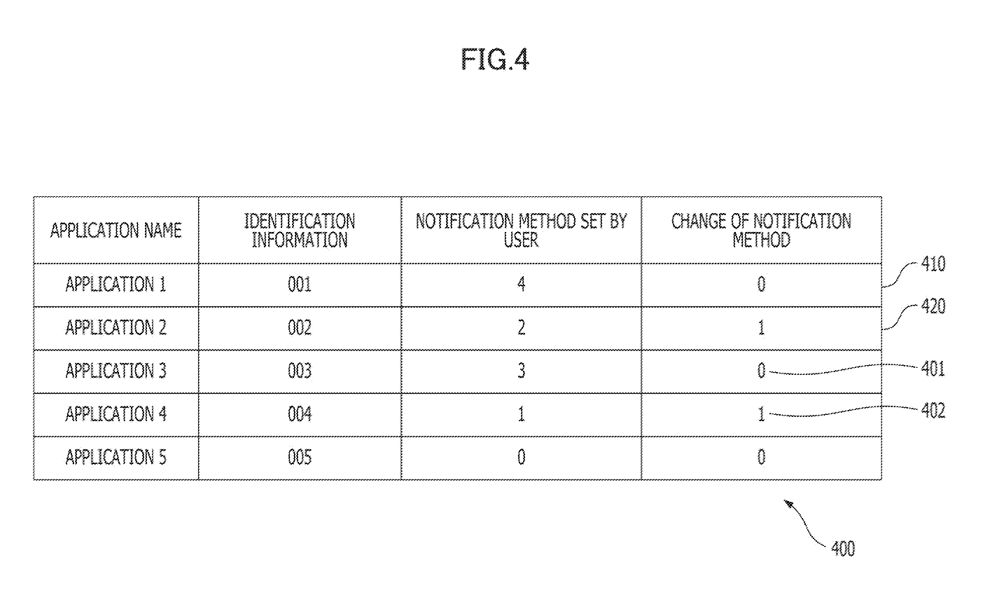

FIG. 4 illustrates an example of a notification method table. In a notification method table 400 of FIG. 4, each row shows, for each application, an event-occurrence notification method and a notification sound volume used when an event occurrence is indicated by sound. The notification method table 400 records, from the leftmost column, application names, application identification information, notification method set by a user, and change notification method.

The notification method set by a user may be represented by a notification method flag, which is a flag indicating an event-occurrence notification method and a notification sound volume set by the user through the operation unit 11. A notification method flag is represented, for example, by any integer from “0” to “5”. If a value of a notification method flag is “0”, the notification method flag indicates that the notification method set by the user is a vibration-based method using the vibrator 16. If a value of a notification method flag is any of “1” to “5”, the notification method flag indicates that a notification method set by the user is a sound-based method using the speaker 14, and the value of the notification method flag corresponds to a notification sound volume level.

The change notification method may be represented by an update flag, which is a flag indicating whether the current notification method to be actually used when an event occurs is a notification method changed by the controller 18. An update flag is represented, for example, by an integer “0” or “1”. If a value of an update flag is “0”, the update flag indicates that the current notification method is a notification method set by the user. If a value of an update flag is “1”, the update flag indicates that the current notification method is a notification method changed by the controller 18.

A row 410, which is the uppermost row, shows that an application name is “Application 1” and application identification information corresponding to the application name is “001”. The row 410 also shows that a notification method set by the user is a sound-based method using the speaker 14 and a notification sound volume is “4”. Additionally, the row 410 shows that the current notification method is a notification method set by the user.

A row 420, which is the second row from the top, shows that an application name is “Application 2” and application identification information corresponding to the application name is “002”. The row 420 also shows that a notification method set by the user is a sound-based method using the speaker 14 and a notification sound volume is “2”. Additionally, the row 420 shows that the current notification method is a notification method changed by the controller 18. That is, the row 420 shows that a notification method to be used when an event occurs is a vibration-based method using the vibrator 16.

When the controller 18 periodically selects a notification method for each application, the notification-method determining unit 22 compares an ambient sound level with a notification sound volume level for every application. For each application, the notification-method determining unit 22 determines a value of an index indicating a notification method to be used. If an ambient sound level is higher than a notification sound volume level, the notification-method determining unit 22 sets the value of the index, for example, to “1” indicating that a vibration-based notification method is to be used. If an ambient sound level is lower than or equal to a notification sound volume level, the notification-method determining unit 22 sets the value of the index, for example, to “0” indicating that a sound-based notification method is to be used. The notification-method determining unit 22 associates the determined value of the index with identification information of the corresponding application.

For an application whose notification method set by the user is a vibration-based notification method, the notification-method determining unit 22 does not have to change the notification method. This is because for such an application, it is possible to assume that the user does not want to receive sound-based notification. Also for such an application, the notification-method determining unit 22 does not have to compare an ambient sound level with a notification sound volume level for the application.

Even for an application whose notification method set by the user is a vibration-based notification method, the notification-method determining unit 22 may change the notification method in accordance with an ambient sound level. In this case, for such an application, to define a criterion for changing the notification method to a sound-based notification method, a given notification sound volume level is set, for example, to “1” or “2”.

For an application whose notification sound volume level has been compared with an ambient sound level, the notification-method determining unit 22 notifies the notification-method updating unit 23 of identification information about the application and an index indicating a notification method to be used. When the controller 18 selects a notification method to be used when an event occurs for a specific application, the notification-method determining unit 22 receives identification information about the application from the controller 18. The notification-method determining unit 22 refers to a notification method table to identify a notification sound volume level corresponding to the identification information received. The notification-method determining unit 22 compares an ambient sound level with the notification sound volume level identified. On the basis of the comparison, the notification-method determining unit 22 determines a value of an index indicating a notification method to be used. If the ambient sound level is higher than the notification sound volume level, the notification-method determining unit 22 sets the value of the index, for example, to “1” indicating that a vibration-based notification method is to be used. If the ambient sound level is lower than or equal to the notification sound volume level, the notification-method determining unit 22 sets the value of the index, for example, to “0” indicating that a sound-based notification method is to be used. The notification-method determining unit 22 notifies the controller 18 of the determined value of the index.

When the controller 18 periodically selects a notification method to be used when an event occurs, the notification-method updating unit 23 stores, for each application, the current notification method to be actually used when an event occurs in the memory 17. Specifically, upon receipt of identification information of the application and an index indicating a notification method to be used from the notification-method determining unit 22, the notification-method updating unit 23 changes, in a notification method table, a value of an update flag corresponding to the identification information on the basis of the received index. Thus, when an event actually occurs, the controller 18 can determine a notification method to be used by referring to the notification method table. This can reduce the time required for the controller 18 to select a notification method when an event occurs.

For example, for the notification method table 400 illustrated in FIG. 4, assume that the notification-method updating unit 23 receives “003” as identification information of an application and a value of an index indicating that a vibration-based notification method is to be used. In this case, the notification-method updating unit 23 changes an update flag 401 corresponding to the identification information “003” from the current value “0” to “1”.

Also, for example, assume that the notification-method updating unit 23 receives “003” as identification information of the application and a value of an index indicating that a sound-based notification method is to be used. In this case, the notification-method updating unit 23 does not change the update flag 401 corresponding to the identification information “003”.

For example, assume that the notification-method updating unit 23 receives “004” as identification information of an application and a value of an index indicating that a sound-based notification method is to be used. In this case, the notification-method updating unit 23 changes an update flag 402 corresponding to the identification information “004” from the current value “1” to “0”.

Also, for example, assume that the notification-method updating unit 23 receives “004” as identification information of the application and a value of an index indicating that a vibration-based notification method is to be used. In this case, the notification-method updating unit 23 does not change the update flag 402 corresponding to the identification information “004”.

The notification-method determining unit 22 stores the updated notification method table 400 in the memory 17. When a low-ambient-sound signal is received from the ambient-sound-level determining unit 21, the notification-method updating unit 23 may set, for every application for which the current notification method is set to a vibration-based notification method by the controller 18, the current notification method to a sound-based notification method. When a low-ambient-sound signal is received from the ambient-sound-level determining unit 21, the notification-method updating unit 23 may change, in a notification method table, every update flag having a value of “1” to “0”. When ambient sound around the mobile phone 1 is low, for every application whose event-occurrence notification method is set to a sound-based notification method by the user, the notification-method updating unit 23 can change the current notification method back to the sound-based notification method.

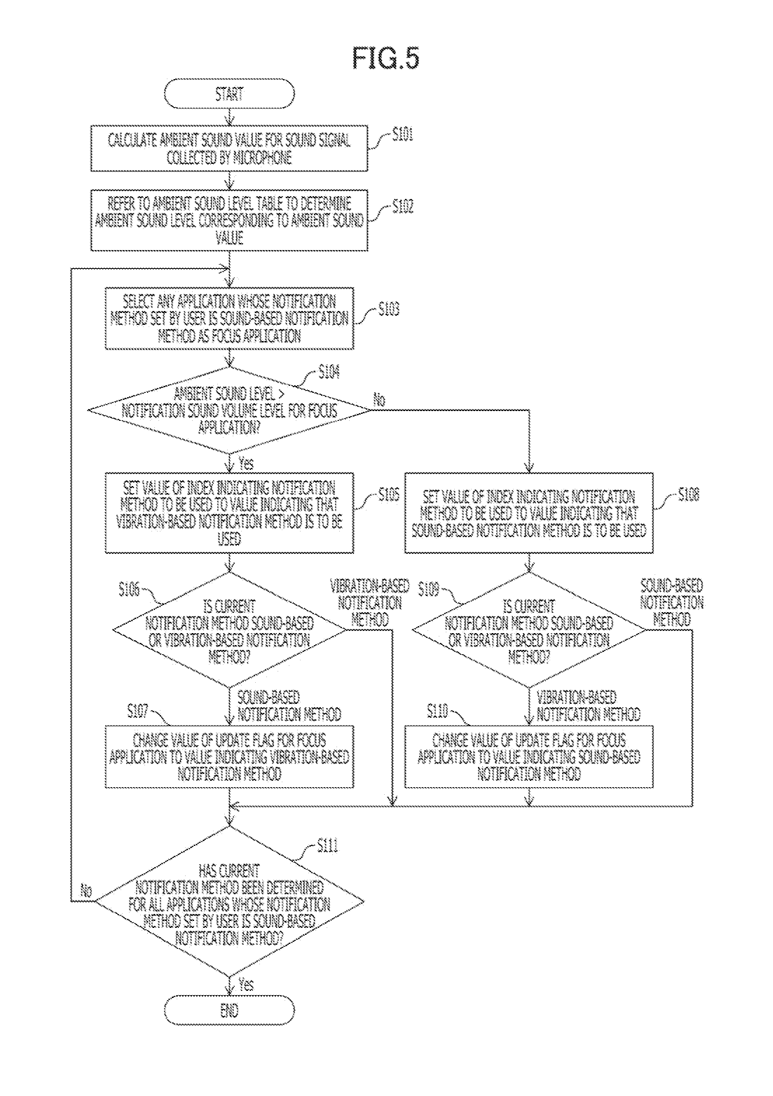

FIG. 5 is an operation flowchart illustrating a process of periodically updating a current notification method to be actually used when an event occurs, the process being performed in accordance with a computer program executed by the controller 18. The controller 18 repeats the updating operation of FIG. 5 at regular intervals. The regular intervals may be determined in accordance with the processing capability of the controller 18. For example, the regular intervals may be every second, every five seconds, every ten seconds, or every minute.

When the controller 18 receives a sound signal collected by the microphone 15, the ambient-sound-level determining unit 21 calculates an ambient sound value that represents the sound signal in decibels (step S101). The ambient-sound-level determining unit 21 refers to an ambient sound level table read from the memory 17 to determine an ambient sound level corresponding to the ambient sound value (step S102). The ambient-sound-level determining unit 21 notifies the notification-method determining unit 22 of the ambient sound level.

The notification-method determining unit 22 refers to a notification method flag to select, as a focus application, any application whose notification method set by the user is a sound-based notification method (step S103). The notification-method determining unit 22 determines whether the ambient sound level is higher than a notification sound volume level for the focus application (step S104).

If the ambient sound level is higher than the notification sound volume level (YES in step S104), the notification-method determining unit 22 sets a value of an index indicating a notification method to be used to a value indicating that a vibration-based notification method is to be used (step S105). The notification-method determining unit 22 notifies the notification-method updating unit 23 of the index indicating the notification method to be used and identification information of the focus application.

The notification-method updating unit 23 refers to a notification method table read from the memory 17 to check a notification method flag and an update flag corresponding to the identification information received from the notification-method determining unit 22. On the basis of values of the notification method flag and update flag, the notification-method updating unit 23 determines whether a current event-occurrence notification method is a sound-based notification method set by the user or a vibration-based notification method changed by the controller 18 (step S106).

If it is determined in step S106 that the current event-occurrence notification method is a sound-based notification method, the notification-method updating unit 23 changes the value of the update flag corresponding to the identification information of the focus application to a value indicating that the current notification method has been changed by the controller 18. In other words, the notification-method updating unit 23 changes the value of the update flag to a value indicating a vibration-based notification method (step S107).

If it is determined in step S106 that the current event-occurrence notification method is a vibration-based notification method, the notification-method updating unit 23 does not change the value of the update flag for the focus application. In other words, the notification-method updating unit 23 maintains a value indicating that the current notification method has been changed by the controller 18, i.e., maintains a value indicating a vibration-based notification method.

If the ambient sound level is lower than or equal to the notification sound volume level (NO in step S104), the notification-method determining unit 22 sets a value of an index indicating a notification method to be used to a value indicating that a sound-based notification method is to be used (step S108). The notification-method determining unit 22 notifies the notification-method updating unit 23 of the index indicating the notification method to be used and identification information of the focus application.

The notification-method updating unit 23 refers to a notification method table read from the memory 17 to check a notification method flag and an update flag corresponding to the identification information received from the notification-method determining unit 22. On the basis of values of the notification method flag and update flag, the notification-method updating unit 23 determines whether a current event-occurrence notification method is a sound-based notification method set by the user or a vibration-based notification method changed by the controller 18 (step S109).

If it is determined in step S109 that the current event-occurrence notification method is a vibration-based notification method, the notification-method updating unit 23 changes the value of the update flag corresponding to the identification information of the focus application to a value indicating that the current notification method is a method set by the user. The notification-method updating unit 23 changes the value of the update flag to a value indicating a sound-based notification method (step S110).

If it is determined in step S109 that the current event-occurrence notification method is a sound-based notification method, the notification-method updating unit 23 does not change the value of the update flag for the focus application. In other words, the notification-method updating unit 23 maintains a value indicating that the current notification method has been set by the user, i.e., maintains a value indicating a sound-based notification method.

After step S107 or step S110, the controller 18 determines whether a current notification method has been determined for all applications whose notification method set by the user is a sound-based notification method (step S111). The determination in step S111 is also made when the update flag has not been changed after step S106 or step S109. If the current event-occurrence notification method has not yet been determined for all applications whose notification method set by the user is a sound-based notification method (NO in step S111), the controller 18 repeats step S103 and the following steps. If the current event-occurrence notification method has been determined for all applications whose notification method set by the user is a sound-based notification method (YES in step S111), the controller 18 ends the process.

When an event related to an application being executed occurs, the controller 18 refers to a notification method table read from the memory 17. By referring to a notification method flag and an update flag corresponding to identification information of the application being executed, the controller 18 can determine whether a sound-based method or a vibration-based method is to be used to provide notification of the occurrence of the event. If it is determined that a sound-based method is to be used to provide notification of the occurrence of the event, the controller 18 operates the speaker 14 to achieve a notification sound volume indicated by the notification method flag. If it is determined that a vibration-based method is to be used to provide notification of the occurrence of the event, the controller 18 operates the vibrator 16.

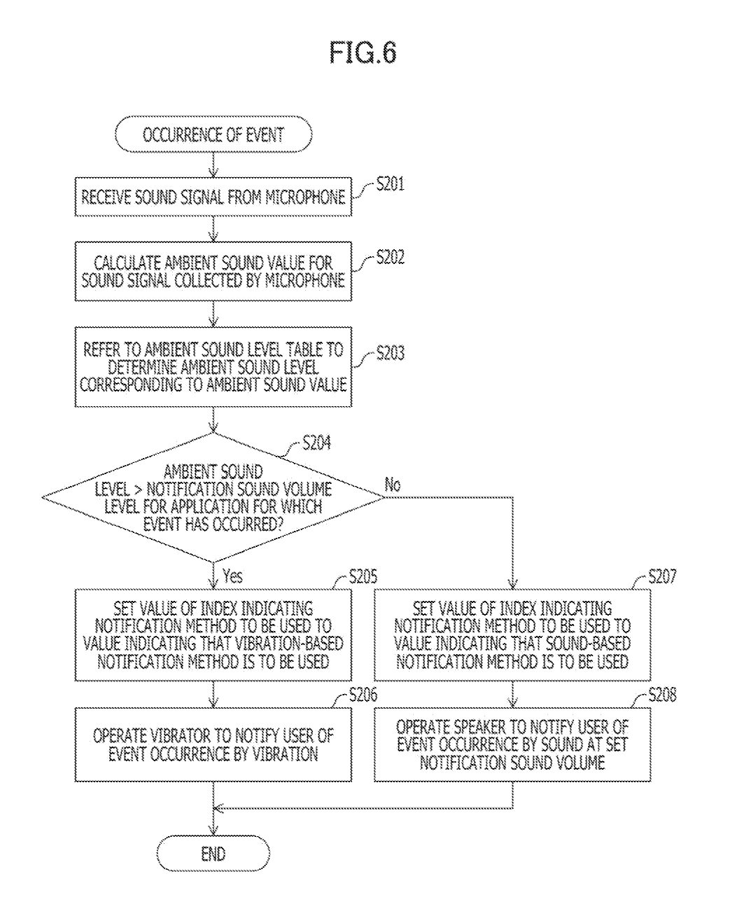

FIG. 6 is an operation flowchart illustrating a process of selecting a notification method for a specific application when an event occurs and providing notification of the occurrence of the event using the selected notification method, the process being performed in accordance with a computer program executed by the controller 18.

Upon detecting that an event has occurred for a specific application, the controller 18 receives a sound signal collected by the microphone 15 (step S201).

Upon receipt of the sound signal from the microphone 15, the ambient-sound-level determining unit 21 calculates an ambient sound value that represents the sound signal in decibels (step S202).

The ambient-sound-level determining unit 21 refers to an ambient sound level table read from the memory 17 to determine an ambient sound level corresponding to the ambient sound value (step S203).

The ambient-sound-level determining unit 21 notifies the notification-method determining unit 22 of the determined ambient sound level.

The notification-method determining unit 22 determines whether the ambient sound level is higher than a notification sound volume level for the application for which the event has occurred (step S204).

If the ambient sound level is higher than the notification sound volume level (YES in step S204), the notification-method determining unit 22 sets a value of an index indicating a notification method to be used to a value indicating that a vibration-based notification method is to be used (step S205). The notification-method determining unit 22 notifies the controller 18 of the index indicating the notification method to be used.

The controller 18 operates the vibrator 16 to notify the user of the occurrence of the event by vibration (step S206). Then, the controller 18 ends the event notification process.

If it is determined in step S204 that the ambient sound level is lower than or equal to the notification sound volume level (NO in step S204), the notification-method determining unit 22 sets a value of an index indicating a notification method to be used to a value indicating that a sound-based notification method is to be used (step S207). The notification-method determining unit 22 notifies the controller 18 of the index indicating the notification method to be used.

The controller 18 operates the speaker 14 to notify the user of the occurrence of the event by sound at the notification sound volume set by the user for the application for which the event has occurred (step S208). Then, the controller 18 ends the event notification process.

As described above, the mobile phone 1 according to the one embodiment measures a volume of ambient sound around the mobile phone 1, and compares the volume of the ambient sound with a notification sound volume for notification of an event occurrence for each application running on the mobile phone 1. For an application whose notification sound volume is lower than the ambient sound volume, the mobile phone 1 changes the event-occurrence notification method from a sound-based notification method to a vibration-based notification method. Thus, even if the level of surrounding ambient sound is high, the mobile phone 1 can reliably notify the user that an event has occurred.

The mobile phone 1 according to the present embodiment does not change the notification method for an application whose notification sound can be realized by the user even when the user is notified of an event occurrence by sound in an ambient sound environment. Thus, the mobile phone 1 of the present embodiment can prevent the user from being bothered by unnecessary switching between different notification methods.

The present embodiment is not limited to that described above. For example, even when a vibration-based notification method using the vibrator 16 is used to provide notification of an event occurrence, the mobile phone 1 may operate the speaker 14, as well as the vibrator 16, to also provide sound-based notification. For a specific application, the mobile phone 1 may allow user setting to prohibit a notification method from being changed in accordance with an ambient sound volume. For example, the user performs a setting operation, through the operation unit 11, to prohibit the change of a notification method for a specific application.

In accordance with the setting operation performed by the user, in a notification method table stored in the memory 17, the controller 18 changes a value of an update flag for the specific application to a value indicating that the change of the notification method is prohibited. The value indicating that the change of the notification method is prohibited may be any value different from a value of an update flag indicating that the current notification method is a method set by the user, and different from a value of an update flag indicating that the current notification method is a method changed by the controller 18.

When determining an event-occurrence notification method in accordance with the procedure illustrated in FIG. 5, the controller 18 refers to the notification method table in step S103 to check a value of an update flag for each application. If an update flag has a value indicating that the change of a notification method is prohibited, the controller 18 does not select an application corresponding to this update flag as a focus application.

When determining an event-occurrence notification method in accordance with the procedure illustrated in FIG. 6, the controller 18 refers to the notification method table before step S201 to check a value of an update flag for an application for which an event has occurred. If the update flag has a value indicating that the change of a notification method is prohibited, the controller 18 does not execute the procedure illustrated in FIG. 6. Instead, the controller 18 refers to the notification method table to use a notification method indicated by a notification method flag for the application for which the event has occurred. Thus, for a specific application, the mobile phone 1 can prohibit the notification method from being changed in accordance with an ambient sound volume.

As a non-sound notification unit that notifies the user of an event occurrence by a human perceivable phenomenon, the mobile phone 1 may have a light-emitting device, such as a light-emitting diode, instead of, or together with, the vibrator 16. For an application whose notification sound volume level is lower than an ambient sound level, the mobile phone 1 can notify the user of an event occurrence by causing the light-emitting device to light up or blink.

The mobile phone 1 may also use the display unit 12 as a non-sound notification unit. For an application whose notification sound volume level is lower than an ambient sound level, the mobile phone 1 can notify the user of an event occurrence by causing the display unit 12 to display information indicating the event that has occurred.

Instead of determining an ambient sound level of ambient sound collected by the microphone 15, the controller 18 of the mobile phone 1 may determine a sound volume value corresponding to a notification sound volume level set by the user. The sound volume value may be a value expressed in the same unit as that of a signal representing a volume of sound collected by the microphone 15. If a volume of ambient sound collected by the microphone 15 is greater than a sound volume value corresponding to a notification sound volume level for an application, the controller 18 may change an event-occurrence notification method to a vibration-based notification method. A sound volume value corresponding to each notification sound volume level is, for example, set in advance on the basis of experiment or simulation. For example, a relationship between each notification sound volume level and the corresponding sound volume value is incorporated in a computer program running on the controller 18.

If there are a plurality of events that can occur for one application and the mobile phone 1 can set a notification sound volume level separately for each event, the mobile phone 1 may select a notification method for each event. If an ambient sound level of ambient sound collected by the microphone 15 is higher than a notification sound volume level set for a specific event, the mobile phone 1 changes a notification method for an occurrence of the specific event to a vibration-based notification method.

For example, for phone calls, the mobile phone 1 may set a notification sound volume level of ring tone for each person registered in an address book. The mobile phone 1 may select a notification method, for each person, by comparing an ambient sound level with a set notification sound volume level of ring tone. When the user is talking on the mobile phone 1, the mobile phone 1 may stop executing a process of selecting an event-occurrence notification method.

With the user's voice, the mobile phone 1 can prevent an event-occurrence notification method from switching to a vibration-based notification method. For example, during a phone call, the mobile phone 1 can determine that the user is talking on the mobile phone 1. When the user is talking on the mobile phone 1, the mobile phone 1 may separate the user's voice from ambient sound around the mobile phone 1 to determine an ambient sound level on the basis of the ambient sound. For example, to separate the user's voice from ambient sound around the mobile phone 1, the mobile phone 1 has a plurality of microphones that are spaced given distances from one another. The controller 18 of the mobile phone 1 estimates the direction of arrival of sound on the basis of differences in time of arrival of the sound at each microphone. If the direction of arrival of sound is within a given angular range from the mobile phone 1, the controller 18 can determine that the sound is the user's voice. If the direction of arrival of sound is outside the given angular range, the controller 18 can determine that the sound is ambient sound. The given angular range can be defined by assuming the position of the user's mouth while the user is talking on the mobile phone 1.

The mobile phone 1 may use another sound source separation technique, such as a blind source separation technique using independent component analysis, to separate the user's voice from ambient sound. For example, when the mobile phone 1 uses a blind source separation technique using independent component analysis, the mobile phone 1 performs filter processing using a separation matrix to separate source signals emitted by respective sound sources from mixed audio signals obtained by a plurality of microphones. The separation matrix is optimized by using the fact that the source signals are statistically independent of one another. The mobile phone 1 can estimate the direction of arrival of sound by multiplying such a separation matrix by a steering vector.

The present invention is applicable not only to mobile phones, but also to other types of portable electronic apparatuses. For example, the present invention is applicable to personal digital assistants and pagers.

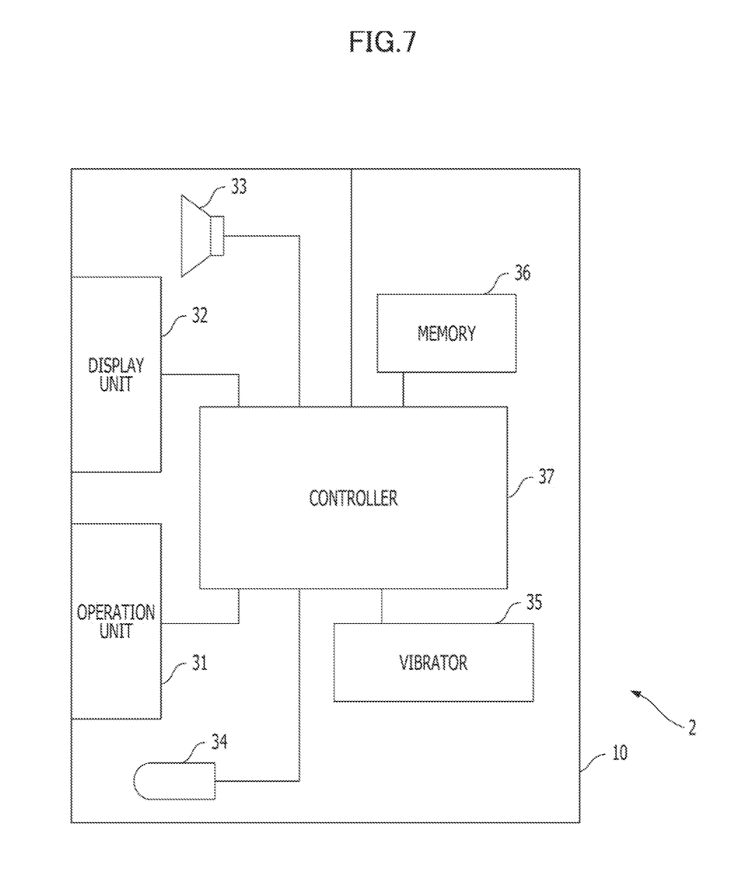

FIG. 7 illustrates a configuration of a personal digital assistant according to another embodiment.

As illustrated in FIG. 7, a personal digital assistant 2 includes an operation unit 31, a display unit 32, a speaker 33, a microphone 34, a vibrator 35, a memory 36, and a controller 37. The personal digital assistant 2 has a housing 30 for accommodating these components. The operation unit 31, the display unit 32, the speaker 33, the microphone 34, the vibrator 35, and the memory 36 are individually connected to the controller 37.

The operation unit 31 and display unit 32 of the personal digital assistant 2 have functions and configurations similar to those of the operation unit 11 and display unit 12 of the mobile phone 1 illustrated in FIG. 1. The speaker 33, microphone 34, and vibrator 35 of the personal digital assistant 2 also have functions and configurations similar to those of the speaker 14, microphone 15, and vibrator 16 of the mobile phone 1 illustrated in FIG. 1. The memory 36 and controller 37 of the personal digital assistant 2 also have functions and configurations similar to those of the memory 17 and controller 18 of the mobile phone 1 illustrated in FIG. 1. The controller 37 is capable of realizing functions illustrated in FIG. 2. Therefore, the detailed description of each component of the personal digital assistant 2 is omitted.

All examples and conditional language recited herein are intended for pedagogical purposes to aid the reader in understanding the principles of the invention and the concepts contributed by the inventor to furthering the art, and are to be construed as being without limitation to such specifically recited examples and conditions. Although the embodiments of the present inventions has been described in detail, it should be understood that the various changes, substitutions, and alterations could be made hereto without departing from the spirit and scope of the invention.

What is claimed is:

1. A radio communication apparatus capable of executing at least one application, the apparatus comprising:
a sound notification unit to provide sound-based notification of an occurrence of an event related to the at least one application;
a non-sound notification unit to provide non-sound-based notification of an occurrence of an event related to the at least one application;
a memory to store a notification sound volume associated with an application, the notification sound volume being a volume of a notification sound produced by the sound notification unit to provide notification of an occurrence of an event related to the application;
a sound collecting unit to collect ambient sound; and
a processor to select a notification method on the basis of whether an ambient sound volume is greater than the notification sound volume associated with the application related to the event occurring, the ambient sound volume being a volume of the ambient sound collected by the sound collecting unit.

2. The radio communication apparatus according to claim 1, wherein
the processor selects the non-sound notification unit when the ambient sound volume is greater than the notification sound volume stored in the memory; and
the processor selects the sound notification unit when the ambient sound volume is less than or equal to the notification sound volume stored in the memory.

3. The radio communication apparatus according to claim 1, wherein
the memory stores an index indicating which of the sound notification unit and the non-sound notification unit is to be used to provide notification of an occurrence of an event related to the at least one application;
the sound collecting unit collects ambient sound at given time intervals;
each time a signal representing the ambient sound volume is received from the sound collecting unit, on the basis of a comparison between the ambient sound volume and the notification sound volume for the at least one application, the processor determines which of the sound notification unit and the non-sound notification unit is to be used to provide notification of an occurrence of an event related to the at least one application, and updates the index on the basis of the determination; and
when an event related to the at least one application occurs, the processor uses the sound notification unit or the non-sound notification unit to provide notification of the occurrence of the event in accordance with the index stored in the memory.

4. The radio communication apparatus according to claim 2, wherein
the memory stores an index indicating which of the sound notification unit and the non-sound notification unit is to be used to provide notification of an occurrence of an event related to the at least one application;
the sound collecting unit collects ambient sound at given time intervals;
each time a signal representing the ambient sound volume is received from the sound collecting unit, on the basis of a comparison between the ambient sound volume and the notification sound volume for the at least one application, the processor determines which of the sound notification unit and the non-sound notification unit is to be used to provide notification of an occurrence of an event related to the at least one application, and updates the index on the basis of the determination; and
when an event related to the at least one application occurs, the processor uses the sound notification unit or the non-sound notification unit to provide notification of the occurrence of the event in accordance with the index stored in the memory.

5. The radio communication apparatus according to claim 1, wherein
the memory stores a notification sound volume for each of a plurality of events related to the at least one application, the notification sound volume being a volume of a notification sound produced by the sound notification unit to provide notification; and
when the ambient sound volume is greater than a notification sound volume set for any of the plurality of events related to the at least one application, the processor causes the non-sound notification unit to provide notification of an occurrence of the event, and when the ambient sound volume is less than or equal to the notification sound volume set for the event, the processor causes the sound notification unit to provide notification of the occurrence of the event.

6. The radio communication apparatus according to claim 1, wherein
the memory stores a notification sound volume for each of a plurality of events related to the at least one application, the notification sound volume being a volume of a notification sound produced by the sound notification unit to provide notification; and
when the ambient sound volume is greater than a notification sound volume set for any of the plurality of events related to the at least one application, the processor causes the non-sound notification unit to provide notification of an occurrence of the event, and when the ambient sound volume is less than or equal to the notification sound volume set for the event, the processor causes the sound notification unit to provide notification of the occurrence of the event.

7. A method for providing notification of an occurrence of an event, the method comprising:
comparing an ambient sound volume with a notification sound volume set for the at least one application and stored in a memory, the ambient sound volume being a volume of ambient sound collected by a sound collecting unit;
causing a non-sound notification unit to provide notification of an occurrence of an event related to the at least one application when the comparison indicates that the ambient sound volume is greater than the notification sound volume; and
causing a sound notification unit to provide notification of an occurrence of an event related to the at least one application when the comparison indicates that the ambient sound volume is less than or equal to the notification sound volume.

8. The method according to claim 7, wherein
the non-sound notification unit provides notification of the occurrence of the event when the ambient sound volume is greater than the notification sound volume stored in the memory; and
the sound notification unit provides notification of the occurrence of the event when the ambient sound volume is less than or equal to the notification sound volume stored in the memory.

9. The radio communication apparatus according to claim 7, wherein
the memory stores an index indicating which of the sound notification unit and the non-sound notification unit is to be used to provide notification of an occurrence of an event related to the at least one application;
the sound collecting unit collects ambient sound at given time intervals;
each time a signal representing the ambient sound volume is received from the sound collecting unit, on the basis of a comparison between the ambient sound volume and the notification sound volume for the at least one application, determining which of the sound notification unit and the non-sound notification unit is to be used to provide notification of an occurrence of an event related to the at least one application, and updating the index on the basis of the determination; and
when an event related to the at least one application occurs, using the sound notification unit or the non-sound notification unit to provide notification of the occurrence of the event in accordance with the index stored in the memory.

10. The radio communication apparatus according to claim 8, wherein
the memory stores an index indicating which of the sound notification unit and the non-sound notification unit is to be used to provide notification of an occurrence of an event related to the at least one application;
the sound collecting unit collects ambient sound at given time intervals;
each time a signal representing the ambient sound volume is received from the sound collecting unit, on the basis of a comparison between the ambient sound volume and the notification sound volume for the at least one application, determining which of the sound notification unit and the non-sound notification unit is to be used to provide notification of an occurrence of an event related to the at least one application, and updating the index on the basis of the determination; and
when an event related to the at least one application occurs, using the sound notification unit or the non-sound notification unit to provide notification of the occurrence of the event in accordance with the index stored in the memory.

11. The radio communication apparatus according to claim 7, wherein
the memory stores a notification sound volume for each of a plurality of events related to the at least one application, the notification sound volume being a volume of a notification sound produced by the sound notification unit to provide notification; and
when the ambient sound volume is greater than a notification sound volume set for any of the plurality of events related to the at least one application, causing the non-sound notification unit to provide notification of an occurrence of the event, and when the ambient sound volume is less than or equal to the notification sound volume set for the event, causing the sound notification unit to provide notification of the occurrence of the event.

12. The radio communication apparatus according to claim 7, wherein
the memory stores a notification sound volume for each of a plurality of events related to the at least one application, the notification sound volume being a volume of a notification sound produced by the sound notification unit to provide notification; and
when the ambient sound volume is greater than a notification sound volume set for any of the plurality of events related to the at least one application, causing the non-sound notification unit to provide notification of an occurrence of the event, and when the ambient sound volume is less than or equal to the notification sound volume set for the event, causing the sound notification unit to provide notification of the occurrence of the event.

13. A computer-readable medium storing program instructions for performing, when executed by a processor, a method of providing notification of an occurrence of an event, the method comprising:
comparing an ambient sound volume with a notification sound volume set for the at least one application and stored in a memory, the ambient sound volume being a volume of ambient sound collected by a sound collecting unit;
causing a non-sound notification unit to provide notification of an occurrence of an event related to the at least one application when the comparison indicates that the ambient sound volume is greater than the notification sound volume; and
causing a sound notification unit to provide notification of an occurrence of an event related to the at least one application when the comparison indicates that the ambient sound volume is less than or equal to the notification sound volume.
